(19) United States
(12) Patent Application Publication
(10) Pub. No.: US 2006/0097313 A1
(43) Pub. Date: May 11, 2006

(54) Semiconductor device and method of manufacturing same

(75) Inventors: Satoshi Yanagisawa, Kanagawa (JP); Satoshi Aida, Kanagawa (JP); Shigeo Kouzuki, Kanagawa (JP); Masaru Izumisawa, Kanagawa (JP); Hironori Yoshioka, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/061,624

(22) Filed: Feb. 22, 2005

(30) Foreign Application Priority Data
Nov. 11, 2004 (JP) 2004-327394

(51) Int. Cl. H01L 31/113; H01L 29/94

(52) U.S. Cl. 257/329; 257/330

(57) ABSTRACT

A semiconductor device comprises a semiconductor layer of a first conductivity type; a first semiconductor pillar layer of the first conductivity type provided on a major surface of the semiconductor layer; a second semiconductor pillar layer of a second conductivity type provided adjacent to the first semiconductor pillar layer; a semiconductor region of the first conductivity type provided between the semiconductor layer and the second semiconductor pillar layer, the semiconductor region having a lower impurity concentration than the semiconductor layer; a semiconductor base layer of the second conductivity type provided on the second semiconductor pillar layer; a semiconductor source region of the first conductivity type selectively provided in the surface of the semiconductor base layer; a gate insulating film provided on the semiconductor base layer between the semiconductor source region and the first semiconductor pillar layer; and a gate electrode provided on the gate insulating film.

### CROSS-REFERENCE TO RELATED APPLICATIONS

This application is based upon and claims the benefit of priority from the prior Japanese Patent Application No. 2004-327394, filed on Nov. 11, 2004; the entire contents of which are incorporated herein by reference.

### BACKGROUND OF THE INVENTION

The invention relates to a semiconductor device and a method of manufacturing the same, and more particularly, to a semiconductor device having a power MOSFET (Metal-Oxide-Semiconductor Field Effect Transistor) structure and a method of manufacturing the same.

Power MOSFETs have been rapidly growing in demand, for example, as a switching component in a charging/discharging circuit for lithium ion battery. Power applications require high breakdown voltage, as well as reduced on-resistance for suppressing power loss. In particular, in a power MOSFET mounted on a battery-driven portable device, it is an urgent task to reduce power consumption of the circuit by decreasing its on-resistance.

However, in conventional power MOSFETs with planar structure, reduction of on-resistance involves decrease of breakdown voltage. That is, it has been difficult to achieve good results simultaneously in both of these characteristics. To solve this problem, the so-called “superjunction structure” has been developed.

Typically, a vertical superjunction MOSFET comprises an n⁺-type substrate, an n⁺-type drain layer formed thereon, and an n⁻-type base layer, p-type base region, n⁺-type source region, gate insulating film, gate electrode, source electrode, and drain electrode epitaxially grown thereon. The n⁻-type base layer contains a region in which n-type and p-type pillar layers are alternately repeated. If the integrated amount of carriers along the repeating direction is below a predetermined value and nearly constant, these low-concentration layers are almost completely depleted by reverse bias applied therebetween. As a result, the n-type pillar layers become a major current path, and thus the on-resistance can be reduced.

However, the manufacturing process for implementing this structure requires a plurality of iterations of epitaxial growth, patterning, and ion implantation of silicon, which results in a highly complex procedure. For this reason, it is difficult to achieve a fine structure and impurity profile as designed. In addition, it is unsuitable for mass production.

In view of these requirements, the inventors have developed a DT (Deep Trench) power MOSFET (hereinafter abbreviated as “DTMOS”) (e.g., Japanese Laid-Open Patent Application 2002-170955). The structure of DTMOS is described in line with its manufacturing process as follows.

First, a trench having a depth of about 10 to 60 micrometers is formed from the surface of an n⁻-layer epitaxially grown on an n⁺-type silicon substrate. Impurities of p-type (e.g., boron) and n-type (e.g., arsenic) having different diffusion coefficients are ion implanted into the sidewall of the trench, and then a thermal diffusion step is performed. Use of p-type impurities having a greater diffusion coefficient than that of n-type impurities results in a p-type pillar layer away from the trench and an n-type pillar layer close to the trench.

Subsequently, insulating film is formed on the inner wall of the trench. The trench is then filled with filler. A p-type base region, n⁺-type source region, insulating gate, and source electrode are formed, and thereby a DTMOS is completed. This structure enables low on-resistance and high breakdown voltage.

However, in this structure, the component breakdown voltage may decrease due to local concentration of electric field. More specifically, since the n-type pillar layer is in contact with the p-type base region of a relatively low concentration, the depletion layer spreads to both the n-type pillar layer and the p-type base region. On the other hand, since the p-type pillar layer of low concentration is in contact with the n⁺-type drain layer of high concentration, the depletion layer in this portion only spreads inside the p-type pillar layer. That is, the electric field strength is higher in the junction portion below the p-type pillar layer where the p-type pillar layer is in contact with the n⁺-type drain layer. This portion may decrease the breakdown voltage of the entire component.

### SUMMARY OF THE INVENITON

According to an aspect of the invention, there is provided a semiconductor device comprising: a semiconductor layer of a first conductivity type; a first semiconductor pillar layer of the first conductivity type provided on a major surface of the semiconductor layer; a second semiconductor pillar layer of a second conductivity type provided adjacent to the first semiconductor pillar layer; a semiconductor region of the first conductivity type provided between the semiconductor layer and the second semiconductor pillar layer, the semiconductor region having a lower impurity concentration than the semiconductor layer; a semiconductor base layer of the second conductivity type provided on the second semiconductor pillar layer; a semiconductor source region of the first conductivity type selectively provided in the surface of the semiconductor base layer; a gate insulating film provided on the semiconductor base layer between the semiconductor source region and the first semiconductor pillar layer; and a gate electrode provided on the gate insulating film.

According to other aspect of the invention, there is provided a semiconductor device comprising: a semiconductor layer of a first conductivity type; and a semiconductor structure provided on a major surface of the semiconductor layer, wherein the semiconductor structure includes: a trench reaching the semiconductor layer; an insulating film provided on an inner wall of the trench; filler filling an inner space of the trench surrounded by the insulating film; a first semiconductor pillar layer of the first conductivity type provided adjacent to the trench; a second semiconductor pillar layer of a second conductivity type provided adjacent to the first semiconductor pillar layer; a semiconductor region of the first conductivity type provided between the semiconductor layer and the second semiconductor pillar layer, the semiconductor region having a lower impurity concentration than the semiconductor layer; a semiconductor base layer of the second conductivity type provided on the second semiconductor pillar layer; a semiconductor source region of the first conductivity type selectively provided in the surface of the semiconductor base layer; a gate insulating film provided on the semiconductor base layer between the semiconductor source region and the first semiconductor pillar layer; and a gate electrode provided on the gate insulating film.

According to other aspect of the invention, there is provided a method of manufacturing a semiconductor device comprising the steps of: in a stacked body of a first semiconductor layer of a first conductivity type and a second semiconductor layer of the first conductivity type formed thereon having a lower impurity concentration than the first semiconductor layer, forming a trench reaching the first semiconductor layer from a surface of the second semiconductor layer; injecting an ion beam of second conductivity type impurities and an ion beam of first conductivity type impurities onto a sidewall of the trench so that the ion beam of the second conductivity type impurities has a greater implantation angle with respect to the sidewall of the trench than the ion beam of the first conductivity type impurities; diffusing the first conductivity type impurities and the second conductivity type impurities to form a first conductivity type pillar layer provided adjacent to the trench, a second conductivity type pillar layer provided adjacent to the first conductivity type pillar layer and away from the trench, and a semiconductor region of the first conductivity type remaining between the first semiconductor layer and the second conductivity type pillar layer; filling the inside of the trench with filler; selectively forming a base region of the second conductivity type in an upper surface of the second conductivity type pillar layer; and forming a source region of the first conductivity type selectively provided in an upper surface of the base region and a gate electrode provided via a gate insulating film on a channel region between the source region and the first conductivity type pillar layer.

### BRIEF DESCRIPTION OF THE DRAWINGS

The present invention will be understood more fully from the detailed description given here below and from the accompanying drawings of the embodiments of the invention. However, the drawings are not intended to imply limitation of the invention to a specific embodiment, but are for explanation and understanding only.

In the drawings:

FIG. 1 is a schematic cross-sectional view of a semiconductor device according to an embodiment of the invention;

FIG. 2 is a cutaway perspective view showing part of a semiconductor device in which the DTMOS unit structure of the embodiment is laterally repeated;

FIGS. 3 to 10 are process cross-sectional views showing part of a method of manufacturing a semiconductor device of the embodiment; and

FIG. 11 is a schematic view showing a partial cross section of a semiconductor device of a variation of the embodiment.

### DETAILED DESCRIPTION

Embodiments of the invention will now be described with reference to the drawings.

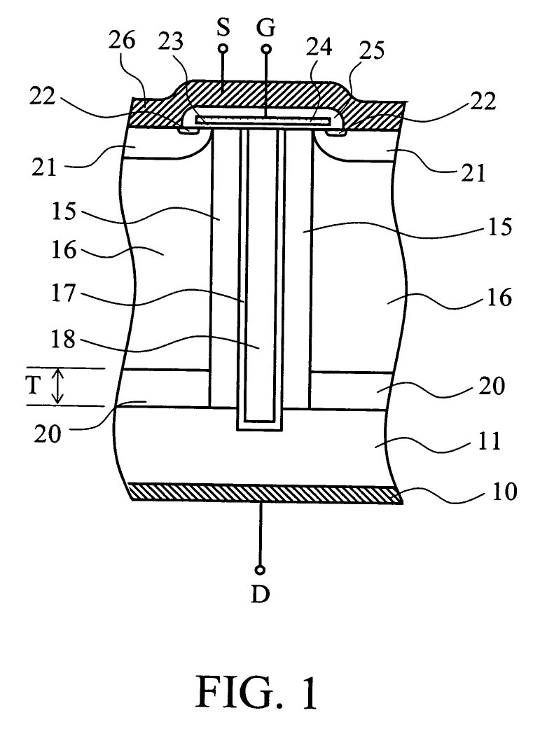

FIG. 1 is a schematic cross-sectional view of a semiconductor device according to an embodiment of the invention.

The semiconductor device of this embodiment has a DTMOS structure formed on an n-type silicon substrate 11. In this embodiment, an n⁻-type region 20 is provided between a p-type pillar layer 16 and the n-type silicon substrate 11.

More specifically, a buried layer 18 is provided on the n-type silicon substrate 11. An oxide film 17 surrounds the buried layer 18. On both sides thereof, an n-type pillar layer 15 and the p-type pillar layer 16 are arranged in this order. The n-type pillar layer 15 is formed adjacently on the n-type silicon substrate 11, whereas the n⁻-type region 20 is provided between the p-type pillar layer 16 and the substrate 11.

A p-type base region 21 is formed on the p-type pillar layer 16 in a planar configuration. An n-type source region 22 is formed in the surface of the p-type base region 21 in a planar configuration. A gate insulating film 23 is provided on the surface of the source region 22 and the n-type pillar layer 15. A gate electrode 24 is provided on the gate insulating film 23. A source electrode 26 is connected to the n-type source region 22. An insulating film 25 is provided between the gate electrode 24 and the source electrode 26. On the other hand, a drain electrode 10 is formed on the rear surface of the silicon substrate 11.

The respective impurity concentrations may be, for example, 1×10¹⁸ cm⁻³ or more for the n-type silicon substrate 11, 2×10¹⁴ to 8×10¹⁵ cm⁻³ or more for the n-type pillar layer 15, 3×10¹⁵ to 1.8×10¹⁶ cm⁻³ or more for the p-type pillar layer 16, 2×10¹³ to 5×10¹⁴ cm⁻³ for the n⁻-type region 20, 5×10¹⁶ to 5×10¹⁷ cm⁻³ for the p-type base region 21, and 5×10¹⁹ to 2×10²⁰ cm⁻³ for the n-type source region 22.

The n-type pillar layer 15 may have a depth of 50 to 60 micrometers, the p-type pillar layer 16 may have a depth of 40 to 50 micrometers, and the n⁻-type region 20 may have a thickness T of about 5 to 10 micrometers.

A predetermined gate voltage applied to the gate electrode 24 results in a channel in the vicinity of the surface of the directly underlying p-type base region 21 to cause conduction between the n-type source region 22 and the adjacent n-type pillar layer 15. This turns on a connection between the source electrode 26 and the drain electrode 10. That is, a current path for each MOSFET is formed in each n-type pillar layer 15. The on-resistance (Ron) can be reduced by increasing the impurity concentration in the n-type pillar layers 15.

Reverse bias applied to the n-type pillar layer 15 and the p-type pillar layer 16 depletes these pillar layers 15 and 16, which results in a high breakdown voltage.

Furthermore, in this embodiment, the n⁻-type region 20 is provided between the n-type substrate 11 of relatively high concentration and the p-type pillar layer 16 of low concentration. This causes the depletion layer to spread over the p-type pillar layer 16 and the n⁻-type region 20, thereby mitigating electric field. As a result, the breakdown voltage can be further enhanced.

More specifically, when a reverse voltage is applied to the p-n junction between the n-type pillar layer 15 and the p-type pillar layer 16, a reverse voltage will be also applied to p-n junctions formed between these layers and their surrounding portions. Consequently, the breakdown voltage must be increased in all of these p-n junctions.

Here, the n-type pillar layer 15 is also in contact with the p-type base region 21, and a p-n junction is formed therebetween. Both the n-type pillar layer 15 and the p-type base region 21 have relatively low impurity concentration. Therefore, application of reverse bias between them causes the depletion layer to spread over both the n-type pillar layer 15 and the p-type base region, which suppresses increase of the electric field strength.

However, in the DTMOS of the comparative example as described above, since the n⁻-type region 20 is not provided and thus the p-type pillar layer 16 of low concentration is in contact with the n⁺-type drain layer 11 of high concentration, the depletion layer in this portion only spreads inside the p-type pillar layer 16. That is, when the n⁻-type region 20 is not provided, the electric field strength becomes higher in the junction portion below the p-type pillar layer 16 where the p-type pillar layer 16 is in contact with the n⁺-type drain layer 11. This portion may decrease the breakdown voltage of the device.

In contrast, according to this embodiment, the n⁻-type region 20 is provided between the n-type substrate 11 of relatively high concentration and the p-type pillar layer 16 of low concentration. This causes the depletion layer to spread over both the p-type pillar layer 16 and the n⁻-type region 20, thereby mitigating electric field. As a result, the breakdown voltage below the p-type pillar layer 16 is also enhanced, and thus the breakdown voltage of the entire semiconductor device is improved.

For example, suppose a DTMOS without the n⁻-type region 20 has a breakdown voltage of 720 volts. In the present embodiment, the breakdown voltage of the DTMOS can be enhanced up to about 740 volts by providing an n⁻-type region 20 having an impurity concentration of 6×10¹³ cm⁻³ and a thickness T of 5 micrometers.

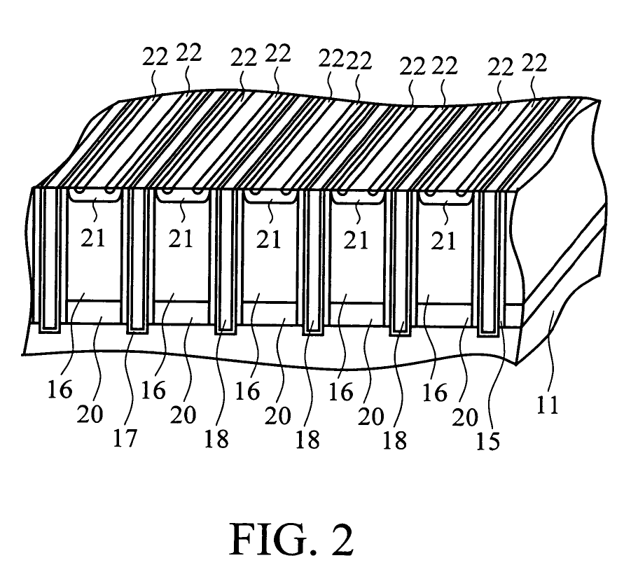

FIG. 2 is a cutaway perspective view showing part of a semiconductor device in which the DTMOS unit structure of the embodiment is laterally repeated.

In such a DTMOS semiconductor device, the p-type pillar layer 16 preferably has an integrated amount of carriers greater than the n-type pillar layer 15 by about 5 to 7 percent so that the turnoff time can be controlled with accuracy. Furthermore, the n-type pillar layer 15 and the p-type pillar layer 16 can be almost completely depleted by selecting the integrated amount of carriers within a predetermined range.

A method of manufacturing a semiconductor device of this embodiment will now be described.

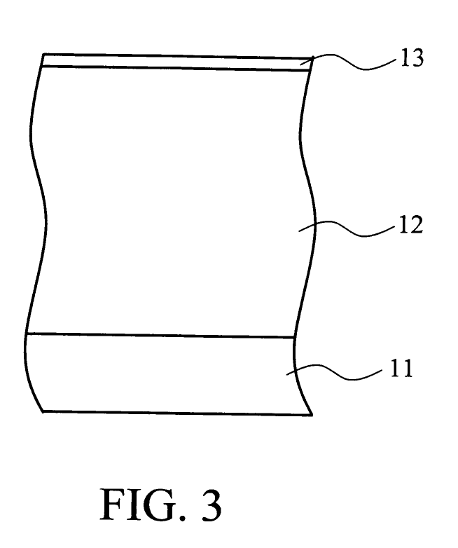

FIGS. 3 to 10 are process cross-sectional views showing part of a method of manufacturing a semiconductor device of the embodiment.

First, as shown in FIG. 3, an n⁻-type layer 12 is epitaxially grown on an n⁺-type silicon substrate 11. Subsequently, a thermal oxide film is formed on the surface of the n⁻-type layer 12 in order to form a mask 13.

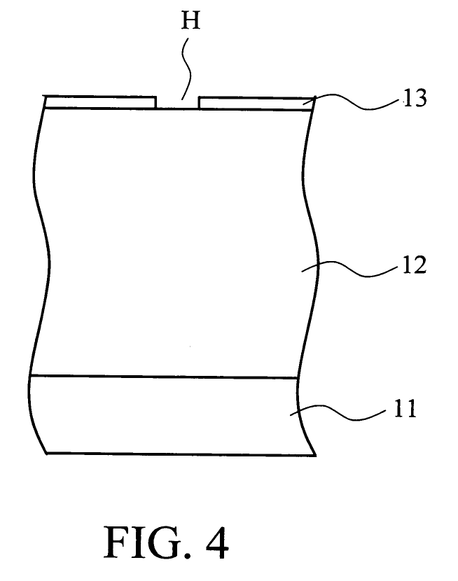

Next, as shown in FIG. 4, the mask 13 is patterned and etched in a predetermined manner to form a hole H.

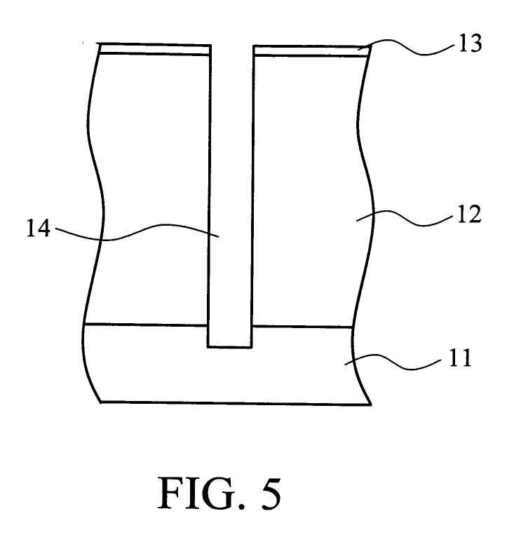

Then, as shown in FIG. 5, a trench 14 reaching the n⁺-type silicon substrate 11 is formed by anisotropic etching through the hole H provided in the mask 13. Preferably, this anisotropic etching is performed by a method such as ICP (Inductively Coupled Plasma) or magnetron RIE (Reactive Ion Etching) that can achieve high anisotropy and high etching rate. This is because the process time can be significantly reduced in forming a deep trench 14.

Next, n-type and p-type impurities are ion implanted. In this respect, the combination of the two types of impurities is determined by comparing their diffusion coefficients to select, in the case of the n-channel type, the combination such that the diffusion coefficient of p-type impurities is greater. For example, arsenic (As) may be used for n-type impurities, and boron (B) for p-type impurities.

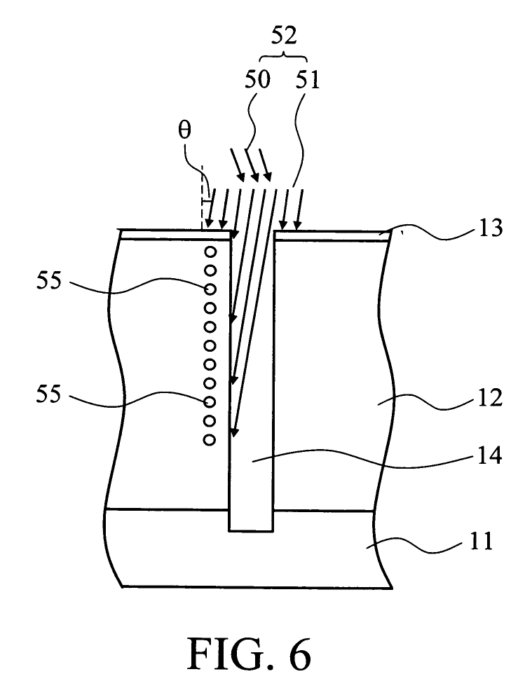

FIG. 6 is a schematic view showing the ion implantation step for p-type impurities.

More specifically, for p-type impurities, for example, boron 55 is ion implanted into the sidewall of the trench 14. At this time, the ion beam is obliquely injected onto the inner sidewall of the trench 14. That is, when the trench 14 is formed generally vertical to the wafer major surface, the ion beam 50, 51 is obliquely injected at an angle θ with respect to the normal of the wafer. The angle θ is determined so that a predetermined thickness of n⁻-type region 20 will remain after the subsequent thermal diffusion step. It should be noted that FIG. 6 illustrates the ion beam 51 for implanting boron into the left sidewall of the trench 14. For ion implantation into the right sidewall of the trench 14, a wafer-rotating or revolving stage may be used to rotate the wafer as appropriate.

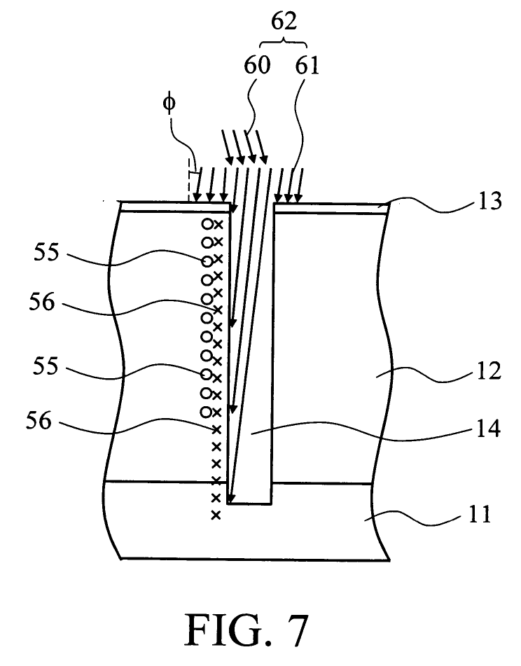

FIG. 7 is a schematic view showing the ion implantation step for n-type impurities.

In this step, it is necessary to implant n-type impurities (e.g., arsenic) even into the trench sidewall of the n⁺-type silicon substrate 11. To this end, the ion implantation angle φ must be smaller than that for the implantation of p-type impurities (θ>φ). In an example step of ion implantation for n-type impurities, the hole H in the mask 13 requires a width of about 5 micrometers or more when the trench 14 has a depth of 60 micrometers, the n⁻-layer 12 has a thickness of 56 micrometers, and the ion implantation angle φ with respect to the wafer normal is 5 degrees.

In order to fabricate the structure of the embodiment successfully, the acceleration energy of the boron beam may preferably higher than the acceleration energy of the arsenic beam, and the doze amount of the boron beam may preferably greater than the doze amount of the arsenic beam.

As an example condition for ion implantation, for boron, the acceleration energy and the dose amount may be 60 keV and 6.7×10¹³ cm⁻², respectively; for arsenic, the acceleration energy and the dose amount may be 40 keV and 3.1×10¹³ cm⁻², respectively. It is to be understood that the ion implantation condition is not limited thereto. Subsequently, the mask 13 is entirely removed by etching, and a thin thermal oxide film (not shown) is newly formed.

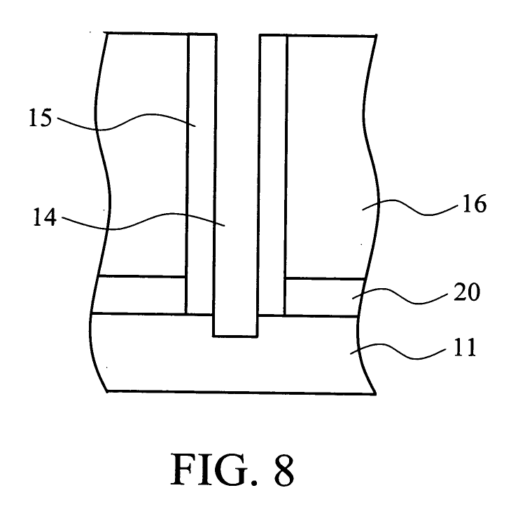

Next, as shown in FIG. 8, p-type and n-type impurities are diffused and activated to form an n-type pillar layer 15 and p-type pillar layer 16. For example, simultaneous diffusion of p-type and n-type impurities can be carried out by thermal diffusion at 1150° C. for 40 hours or more. Here, boron and arsenic may be used for p-type and n-type impurities, respectively. Because boron has a diffusion coefficient sufficiently higher than arsenic, the n-type pillar layer 15 is formed in the vicinity of the inner wall surface of the trench 14, while the p-type pillar layer 16 is formed in the region far from the trench 14 where boron is diffused more deeply. In the center area between adjacent trenches 14, diffusion of boron from both sides contributes to forming the p-type pillar layer 16.

At this time, as described above with reference to FIGS. 6 and 7, selection of the ion implantation angle θ for p-type impurities to be higher than the ion implantation angle φ for n-type impurities leaves a region between the p-type pillar layer 16 and the n⁺-type silicon substrate 11 where p-type impurities are not implanted. This region serves as the n⁻-type region 20.

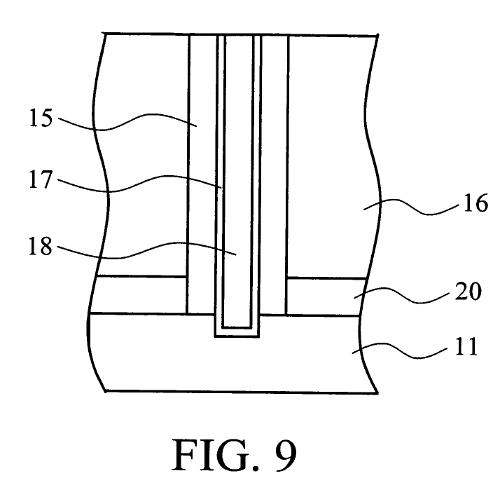

Next, as shown in FIG. 9, the trench 14 is buried. More specifically, an insulating film (e.g., thermal oxide film) 17 is formed on the inner wall of the trench 14. Filler such as silicon oxide, silicon nitride, polysilicon, and amorphous silicon is deposited by vapor phase deposition or other method to bury the trench 14. Subsequently, chemical mechanical polishing (CMP) method and etching are used to planarize the surface of the wafer.

In this step, the trench may be filled with filler after thin film of silicon nitride or silicon oxide is formed on the inner wall of the trench 14. At this time, particulate or porous material can be used for the filler to mitigate any distortion due to thermal stress caused by difference of material between the trench and its surrounding semiconductor portions.

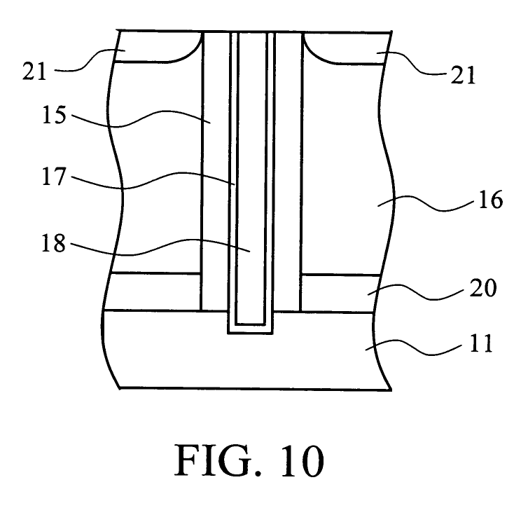

Next, as shown in FIG. 10, the p-type base region 21 is formed. For example, a mask (not shown) is formed on the wafer surface, p-type impurities are diffused through a hole in the mask in a planar configuration, and thereby the p-type base region 21 can be formed. Subsequently, a gate insulating film 23 and an n⁺-source region 21 are formed, and then a gate electrode 24, interlayer insulating film 25, source electrode 26, and drain electrode 10 are formed. The relevant part of DTMOS of this embodiment is thus completed.

As described above, according to the manufacturing method of this embodiment, the p-type pillar layer 16 and n-type pillar layer 15 can be formed by ion implantation at an oblique angle into a deep trench 14. This is a significantly simplified manufacturing method as compared to the process of forming a superjunction structure by repeating a plurality of times the step of epitaxially growing an n⁻-layer and the step of ion implantation for p-type impurities.

In addition, since the junction between the n⁻-type region 20 and the p-type pillar layer 16 is formed by ion implantation, the breakdown voltage, which affects the characteristics of the power device, can be controlled with high accuracy. If ion implantation via the trench is not used but the conventional manufacturing method that repeats epitaxial growth and ion implantation a plurality of times is used, the location of and concentration in the p-n junction are varied in every step of epitaxial growth and thermal diffusion. It is thus difficult to control the p-n junction location between the n⁻-type region 20 and p-type pillar layer 16 with accuracy. As a result, the breakdown voltage is prone to be decreased and subjected to variations. In contrast, according to this embodiment, the n⁻-type region 20 can be formed definitely and easily.

Furthermore, according to this embodiment, since the p-type pillar layer 16 and the n-type pillar layer 15 are formed by ion implantation method, the concentration in these layers can be controlled with accuracy. This results in a semiconductor having an excellent turnoff time (which significantly depends on concentration variations in the pillar layers) and low on-resistance with improved reproducibility.

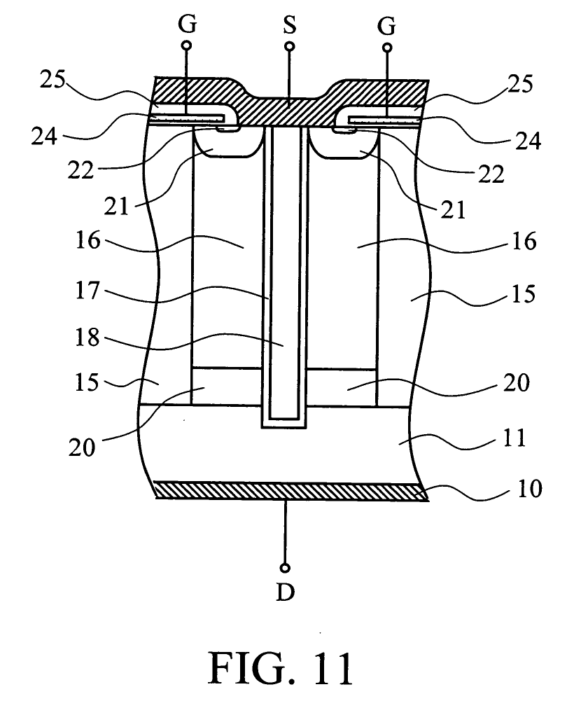

FIG. 11 is a schematic view showing a partial cross section of a semiconductor device of a variation of the embodiment. With respect to this figure, elements similar to those described with reference to FIGS. 1 to 10 are marked with the same numerals and are not described in detail.

In this variation, a trench, filled with insulating film 17 and filler 18, is provided in a center area of the p-type pillar layer 16. In manufacturing this DTMOS, impurities may be selected so that the p-type impurities have a higher diffusion coefficient than the n-type impurities. More specifically, as described above with reference to FIG. 5, after a deep trench 14 is formed in the n⁻-layer 12, p-type and n-type impurities are doped into the inner wall of the trench 14 by ion implantation method with an oblique injection angle. At this time, as shown in FIG. 11, the n-type pillar layer 15 can be formed far from the trench and the p-type pillar layer 16 can be formed in the vicinity of the trench by doping n-type impurities having a high diffusion coefficient and p-type impurities having a low diffusion coefficient and applying heat treatment.

Again, the ion implantation angle for p-type impurities (angle θ in FIG. 6) is set to be greater than the ion implantation angle for n-type impurities (angle φ in FIG. 7) to provide an n⁻-type region 20 so that the p-type pillar layer 16 and the n⁺-type silicon substrate 11 do not directly form a p-n junction. In this way, a DTMOS is obtained that has low on-resistance characteristics and significantly improved breakdown voltage characteristics.

In the foregoing, the conductivity type for each element may be reversed in the structure shown in FIGS. 1 to 11.

More specifically, in the structure shown in FIGS. 1 to 10, the silicon substrate 11 may be of p⁺-type. Since the MOSFET will be of p-channel, a p-type pillar layer may be formed in the vicinity of the trench, and an n-type pillar layer may be provided away from the trench, above which an n-type base region and a p⁺-type source region may be provided. In this case, a p⁻-type region is provided between the n-type pillar layer provided away from the trench and the p⁺-type silicon substrate 11. In this way, since electric field is mitigated below the n-type pillar layer, the breakdown voltage of the DTMOS can be similarly improved. It should be noted here that impurities may be selected so that the n-type impurities have a higher diffusion coefficient than the p-type impurities.

Similarly, the conductivity type for each element can be reversed in the variation shown in FIG. 11. More specifically, the silicon substrate is of p⁺-type. Since the MOSFET will be of p-channel, an n-type pillar layer may be formed in the vicinity of the trench, above which an n-type base region and a p⁺-type source region may be provided, and a p-type pillar layer may be provided away from the trench. In this case, for p-type impurities, an element having a high diffusion coefficient such as boron can be used, and for n-type impurities, arsenic can be used.

The embodiment of the invention has been described with reference to specific examples. However, the invention is not limited to these specific examples.

For example, any appropriate modification by those skilled in the art with respect to material, conductivity type, carrier concentration, impurities, thickness, and positional relationship of various elements of the semiconductor device, and procedure and condition for each step of the manufacturing method described above is also encompassed within the scope of the invention as long as it comprises the feature of the invention.

Any other configuration of the above-described semiconductor device and the manufacturing method thereof that is selected as appropriate by those skilled in the art from among known configurations is also encompassed within the scope of the invention as long as it comprises the feature of the invention.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A semiconductor device comprising:
a semiconductor layer of a first conductivity type;
a first semiconductor pillar layer of the first conductivity type provided on a major surface of the semiconductor layer;
a second semiconductor pillar layer of a second conductivity type provided adjacent to the first semiconductor pillar layer;
a semiconductor region of the first conductivity type provided between the semiconductor layer and the second semiconductor pillar layer, the semiconductor region having a lower impurity concentration than the semiconductor layer;
a semiconductor base layer of the second conductivity type provided on the second semiconductor pillar layer;
a semiconductor source region of the first conductivity type selectively provided in the surface of the semiconductor base layer;
a gate insulating film provided on the semiconductor base layer between the semiconductor source region and the first semiconductor pillar layer; and
a gate electrode provided on the gate insulating film.

2. The semiconductor device according to claim 1, wherein the impurities determining the conductivity type of the second semiconductor pillar layer have a greater diffusion coefficient than the impurities determining the conductivity type of the first semiconductor pillar layer.

3. The semiconductor device according to claim 2, wherein the impurities determining the conductivity type of the second semiconductor pillar layer are boron, and the impurities determining the conductivity type of the first semiconductor pillar layer are arsenic.

4. The semiconductor device according to claim 1, wherein an integrated amount of carriers of the second semiconductor pillar layer is greater than an integrated amount of carriers of the first semiconductor pillar layer.

5. The semiconductor device according to claim 4, wherein an integrated amount of carriers of the second semiconductor pillar layer is greater than an integrated amount of carriers of the first semiconductor pillar layer by 5 to 7 percents.

6. The semiconductor device according to claim 1, wherein a depletion layer spreads over both the second semiconductor pillar layer and the semiconductor region when a reverse bias voltage is applied between the first and second semiconductor pillar layers.

7. The semiconductor device according to claim 1, wherein an impurity concentration of the semiconductor region is 2×10¹³ to 5×10¹⁴ cm⁻³, and a for the n⁻-type region 20, and a thickness of the semiconductor region is 5 to 10 micrometers.

8. A semiconductor device comprising:
a semiconductor layer of a first conductivity type; and
a semiconductor structure provided on a major surface of the semiconductor layer, wherein
the semiconductor structure includes:
a trench reaching the semiconductor layer;
an insulating film provided on an inner wall of the trench;
filler filling an inner space of the trench surrounded by the insulating film;
a first semiconductor pillar layer of the first conductivity type provided adjacent to the trench;
a second semiconductor pillar layer of a second conductivity type provided adjacent to the first semiconductor pillar layer;
a semiconductor region of the first conductivity type provided between the semiconductor layer and the second semiconductor pillar layer, the semiconductor region having a lower impurity concentration than the semiconductor layer;
a semiconductor base layer of the second conductivity type provided on the second semiconductor pillar layer;
a semiconductor source region of the first conductivity type selectively provided in the surface of the semiconductor base layer;
a gate insulating film provided on the semiconductor base layer between the semiconductor source region and the first semiconductor pillar layer; and
a gate electrode provided on the gate insulating film.

9. The semiconductor device according to claim 8, wherein the impurities determining the conductivity type of the second semiconductor pillar layer have a greater diffusion coefficient than the impurities determining the conductivity type of the first semiconductor pillar layer.

10. The semiconductor device according to claim 9, wherein the impurities determining the conductivity type of the second semiconductor pillar layer are boron, and the impurities determining the conductivity type of the first semiconductor pillar layer are arsenic.

11. The semiconductor device according to claim 8, wherein an integrated amount of carriers of the second semiconductor pillar layer is greater than an integrated amount of carriers of the first semiconductor pillar layer.

12. The semiconductor device according to claim 11, wherein an integrated amount of carriers of the second semiconductor pillar layer is greater than an integrated amount of carriers of the first semiconductor pillar layer by 5 to 7 percents.

13. The semiconductor device according to claim 8, wherein a depletion layer spreads over both the second semiconductor pillar layer and the semiconductor region when a reverse bias voltage is applied between the first and second semiconductor pillar layers.

14. The semiconductor device according to claim 8, wherein an impurity concentration of the semiconductor region is 2×10¹³ to 5×10¹⁴ cm⁻³, and a for the n⁻-type region 20, and a thickness of the semiconductor region is 5 to 10 micrometers.

15. A method of manufacturing a semiconductor device comprising the steps of:
in a stacked body of a first semiconductor layer of a first conductivity type and a second semiconductor layer of the first conductivity type formed thereon having a lower impurity concentration than the first semiconductor layer, forming a trench reaching the first semiconductor layer from a surface of the second semiconductor layer;
injecting an ion beam of second conductivity type impurities and an ion beam of first conductivity type impurities onto a sidewall of the trench so that the ion beam of the second conductivity type impurities has a greater implantation angle with respect to the sidewall of the trench than the ion beam of the first conductivity type impurities;
diffusing the first conductivity type impurities and the second conductivity type impurities to form a first conductivity type pillar layer provided adjacent to the trench, a second conductivity type pillar layer provided adjacent to the first conductivity type pillar layer and away from the trench, and a semiconductor region of the first conductivity type remaining between the first semiconductor layer and the second conductivity type pillar layer;
filling the inside of the trench with filler;
selectively forming a base region of the second conductivity type in an upper surface of the second conductivity type pillar layer; and
forming a source region of the first conductivity type selectively provided in an upper surface of the base region and a gate electrode provided via a gate insulating film on a channel region between the source region and the first conductivity type pillar layer.

16. The method of manufacturing a semiconductor device according to claim 15, wherein the second conductivity type impurities have a greater diffusion coefficient than the first conductivity type impurities.

17. The method of manufacturing a semiconductor device according to claim 16, wherein the second conductivity type impurities are boron, and the first conductivity type impurities are arsenic.

18. The method of manufacturing a semiconductor device according to claim 15, wherein the ion beam of the first conductivity type impurities is injected onto a whole surface of the sidewall, and the ion beam of the second conductivity type impurities is injected onto the sidewall except a lower part thereof.

19. The method of manufacturing a semiconductor device according to claim 15, wherein an acceleration energy of the ion beam of the second conductivity type impurities is higher than an acceleration energy of the ion beam of the first conductivity type impurities.

20. The method of manufacturing a semiconductor device according to claim 15, wherein a dose amount of the ion beam of the second conductivity type impurities is greater than a dose amount of the ion beam of the first conductivity type impurities.
